(19) United States
(12) Patent Application Publication
(10) Pub. No.: US 2010/0062593 A1
(43) Pub. Date: Mar. 11, 2010

(54) METHOD FOR PREPARING MULTI-LEVEL FLASH MEMORY DEVICES

(75) Inventors: CHUNG WE PAN, PINGTUNG COUNTY (TW); MING YU HO, TAICHUNG COUNTRY (TW); CHIH PING CHUNG, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/207,740

(22) Filed: Sep. 10, 2008

(51) Int. Cl. H01L 21/28

(52) U.S. Cl. 438/591; 257/E21.18

(57) ABSTRACT

A method for preparing a multi-level flash memory device comprises forming a dielectric stack including a charge-trapping layer on a semiconductor substrate, forming an insulation structure having a depression on the charge-trapping layer, removing a portion of the charge-trapping layer from the depression such that the charge-trapping layer is segmented to form a plurality of storage nodes, forming a gate oxide layer isolating the storage nodes and forming a damascene gate including a polysilicon layer filling the depression.

### BACKGROUND OF THE INVENTION

(A) Field of the Invention

The present invention relates to a method for preparing a multi-level flash memory device, and more particularly, to a method for preparing a multi-level flash memory device having a damascene gate.

(B) Description of the Related Art

Flash memory has been widely applied to the data storage of digital products such as laptop computers, digital assistants, cell phones, digital cameras, digital recorders, and MP3 players. Recent flash memory design incorporates a silicon-oxide-nitride-oxide-silicon (SONOS) structure, which is widely used in flash memory since it possesses the advantages of a thinner memory cell and a simpler fabrication process.

U.S. Pat. No. 6,011,725 discloses non-volatile electrically erasable programmable read only memory (EEPROM) capable of storing two bits of information having a nonconducting charge trapping dielectric, such as silicon nitride, sandwiched between two silicon dioxide layers acting as electrical insulators. The invention includes a method of programming, reading and erasing the two bit EEPROM device. The nonconducting dielectric layer functions as an electrical charge trapping medium. A conducting gate layer is placed over the upper silicon dioxide layer. A left and a right bit are stored in physically different areas of the charge trapping layer, near the left and right regions of the memory cell, respectively.

The EEPROM in U.S. Pat. No. 6,011,725 has the advantage of providing non-volatile storage of two bits of information in a single-transistor memory cell, increasing the storage density over that of a memory device storing one bit of data per storage transistor. However, scaling the EEPROM down to smaller sizes may present difficulties. In particular, operation of the EEPROM requires the ability to inject charges into separate regions in the silicon nitride layer. As the width of the silicon nitride layer decreases, the distance between regions may become too small, which may result in merging of the regions.

US 2006/0186480 discloses a charge-trapping memory device and method for production. A thin SiGe layer is provided as an additional lower gate electrode layer and is arranged between a thin gate oxide and a gate electrode layer, preferably of polysilicon. The SiGe layer can be etched selectively to the gate electrode and the gate oxide and is laterally removed near the source/drain regions in order to form recesses, which are subsequently filled with a material that is appropriate for charge trapping. The device structure and production method are appropriate for an integration scheme comprising local interconnects of memory cells, a CMOS logic periphery and means to compensate differences of the layer levels in the array and the periphery.

US 2007/0126047 discloses a non-volatile semiconductor memory device and method for manufacturing the same. In a non-volatile semiconductor memory device having a MONOS structure, a memory cell section for storing information, and a periphery circuitry section for writing and reading the information with respect to the memory cell section are formed in the surface region of a silicon substrate. A plurality of memory cells is formed in the memory cell section, while a plurality of periphery circuitry transistors are formed also in the periphery circuitry section. Since the periphery circuitry transistor has a structure wherein no electric charge accumulation layer exists, it is possible to prevent electric charge injection to the periphery circuitry transistor, whereby hot carrier characteristics of the periphery circuitry transistor are improved.

Byung Yong Choi et al. discloses a 2-bit/cell SONOS memory transistor (See, “Highly Scalable and Reliable 2-bit/cell SONOS Memory Transistor beyond 50 nm NVM Technology Using Outer Sidewall Spacer Scheme with Damascene Gate Process”, IEEE 2005 Symposium on VLSI Technology Digest of Technical Papers, pp. 1118-119). Byung Yong Choi et al. presents a 2-bit/cell SONOS memory transistor and investigate its scalability and reliability beyond 50 nm NVM technology. This new memory, which is implemented by the damascene gate and newly developed outer sidewall spacer processes, shows not only stable 2-bit operation but also high reliabilities (>10/sup 5/endurance and good retention at 150/spl deg/C) down to 80 nm gate length that applies to next-generation NVM technology. In addition, dimensional effect (the lateral distance between two storage nodes) on the memory operation is reported to approach the ultimate scaling limit of 2-bit/cell SONOS memory transistor.

### SUMMARY OF THE INVENTION

One aspect of the present invention provides a method for preparing a multi-level flash memory device having a damascene gate, which can prevent the storage nodes from being merged as the size of the flash memory device is reduced.

A method for preparing a multi-level flash memory device according to this aspect of the present invention comprises forming a dielectric stack including a charge-trapping layer on a semiconductor substrate, forming an insulation structure having a depression on the charge-trapping layer, removing a portion of the charge-trapping layer from the depression such that the charge-trapping layer is segmented to form a plurality of storage nodes, forming a gate oxide layer isolating the storage nodes and forming a damascene gate including a polysilicon layer filling the depression.

As the size of the flash memory is reduced, the distance between the charge-trapping regions of the conventional flash memory may become too small, which in the prior art may result in merging of the charge-trapping regions. In contrast, the present invention forms the storage nodes and then isolates the storage nodes by using insulation material; therefore, the storage nodes are prevented from merging, even as the size of the flash memory is reduced.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 7 illustrate a method for preparing a multi-level flash memory device according to one embodiment of the present invention;

FIG. 8 to FIG. 10 illustrate a method for preparing a multi-level flash memory device according to another embodiment of the present invention; and

FIG. 11 to FIG. 17 illustrate a method for preparing a multi-level flash memory device according to another embodiment of the present invention.

### DETAILED DESCRIPTION OF THE INVENTION

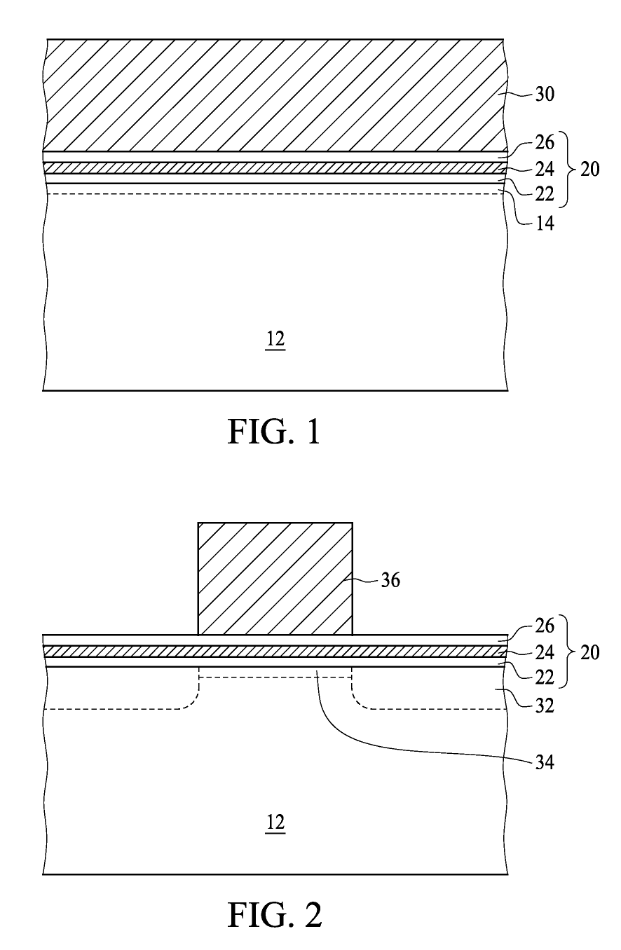

FIG. 1 to FIG. 7 illustrate a method for preparing a multi-level flash memory device 10 according to one embodiment of the present invention. A dielectric stack 20 is formed on a semiconductor substrate 12 and a dielectric layer 30 such as a silicon nitride layer is then formed on the dielectric stack 20 by the deposition process. An implanting process may be performed before the forming of the dielectric stack 20 to implant dopants into the semiconductor substrate 12 to adjust the carrier density in the upper region 14 of the semiconductor substrate 12.

The dielectric stack 20 may include a bottom dielectric layer 22 positioned on the semiconductor substrate 12, a top dielectric layer 26 and a charge-trapping layer 24 sandwiched between the bottom dielectric layer 22 and the top dielectric layer 26. In one embodiment of the present invention, the bottom dielectric layer 22 is a silicon oxide layer formed by the thermal oxidation process, the top dielectric layer 26 is a silicon oxide layer formed by the thermal oxidation process or the deposition process, and the charge-trapping layer 24 is a silicon nitride layer formed by the deposition process.

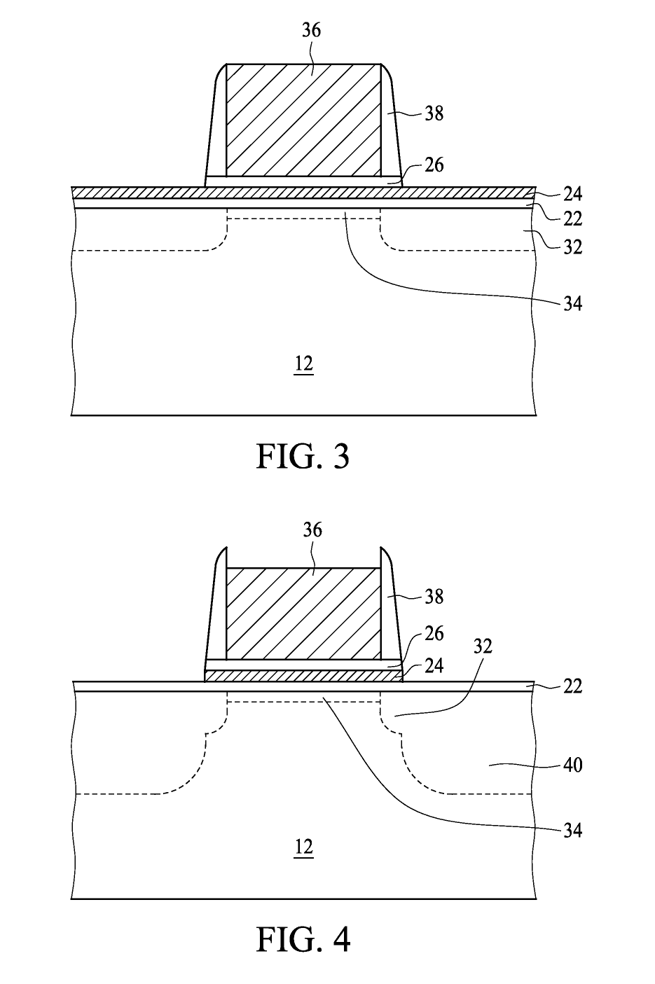

Referring to FIG. 2, the photolithographic process and the etching process are performed to remove a portion of the dielectric layer 30 to form a dielectric block 36, and an implanting process is then performed to form lightly doped regions 32 in the semiconductor substrate 12 adjacent to the dielectric block 36. In particular, a carrier channel 34 is formed between the lightly doped regions 32 in the semiconductor substrate 12. Subsequently, a spacer 38 is formed on the sidewall of the dielectric block 36 by using the deposition process followed by the etching process. In one embodiment of the present invention, the spacer 38 is formed of silicon oxide, and the spacer etching process also removes a portion of the top dielectric layer 26 to expose the charge-trapping layer 24, as shown in FIG. 3.

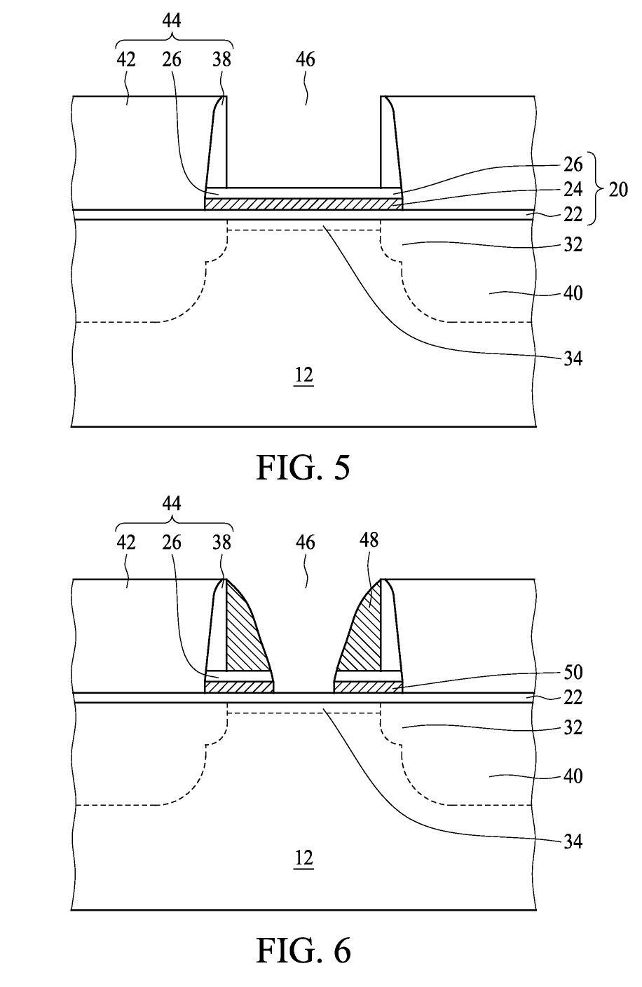

Referring to FIG. 4, an etching process is performed to remove a portion of the dielectric block 36 and the charge-trapping layer 24 not covered by the spacer 38 and the top dielectric layer 26, and an implanting process is then performed to form heavily doped regions 40 in the semiconductor substrate 12 adjacent to the spacer 38. Subsequently, a deposition process is performed to form a dielectric layer 42 on the semiconductor substrate 12 followed by a planarization process such as the chemical-mechanical polishing process, and an etching process is then performed to remove the dielectric block 36 to form a depression 46 in the spacer 38, as shown in FIG. 5. In one embodiment of the present invention, the dielectric layer 42 is formed of silicon oxide, and the etching process can selectively remove the dielectric block 36 including silicon nitride. In particular, the top dielectric layer 26, the spacer 38 and the dielectric layer 42 form an insulation structure 44 with the depression 46 positioned inside the insulation structure 44 and on the bottom dielectric layer 22.

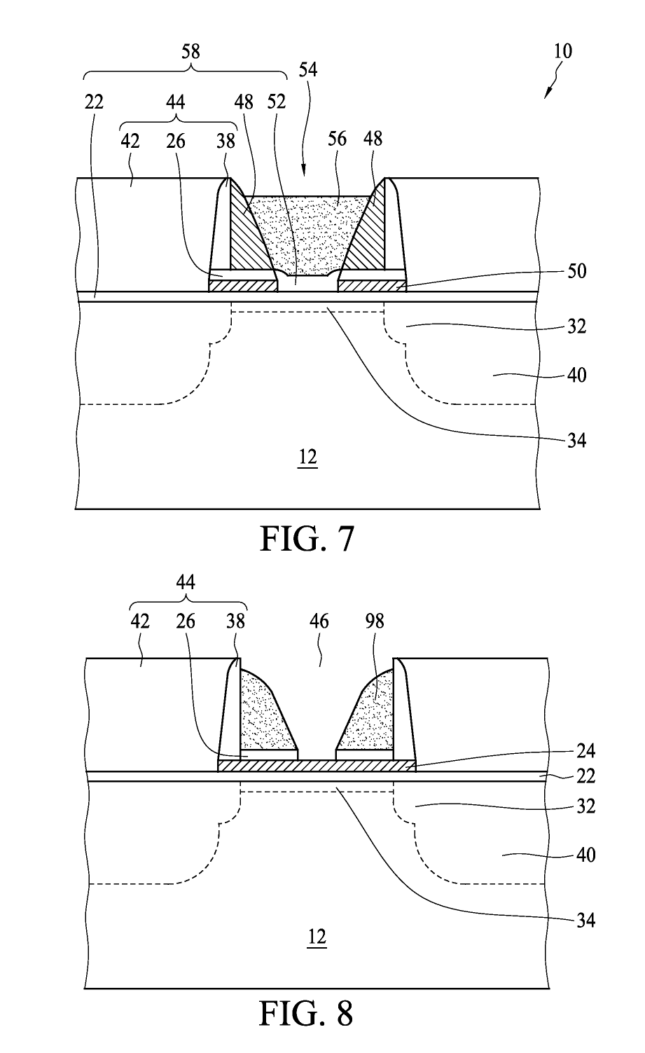

Referring to FIG. 6, a spacer 48 such as an oxide spacer is formed in the depression 46, i.e., on the sidewall of the spacer 38, by using the deposition process followed by the spacer etching process, and another etching process is then performed to remove a portion of the charge-trapping layer 24 not covered by the spacer 48 such that the charge-trapping layer 24 is segmented to form a plurality of storage nodes 50 on the bottom dielectric layer 22. In one embodiment of the present invention, the spacer 48 is formed of silicon oxide, and the etching process can selectively remove the charge-trapping layer 24 including silicon nitride from the depression 46. Subsequently, an oxidation process such as the wet oxidation process is performed to form a gate oxide layer 52 between the storage nodes 50 to electrically isolate the storage nodes 50, and a damascene gate 54 including a polysilicon layer 56 filling the depression 46 is formed by the deposition process followed by the etching process, as shown in FIG. 7.

The bottom dielectric layer 22, the insulation structure 44, the spacer 48 and the gate oxide layer 52 can be considered as a dielectric structure 58 positioned on the semiconductor substrate 12, while the storage nodes 50 are embedded in the dielectric structure 58. In addition, the carrier channel 34 is positioned between the lightly doped region 32 in the semiconductor substrate 12, and a portion of the storage nodes 50 is positioned on the carrier channel 34, while the other portion of the storage nodes 50 is positioned on the lightly doped region 32. Furthermore, the gate oxide layer 52 of the dielectric structure 58 is positioned between the storage nodes 50, and the polysilicon layer 56 of the damascene gate 54 is positioned on the gate oxide layer 52. The polysilicon layer 56 of the damascene gate 54 is positioned in the dielectric structure 58 and above the storage nodes 50. In addition, the polysilicon layer 56 has a tapering profile with larger width at the top, and a bottom end of the polysilicon layer 56 contacts the gate oxide layer 52 between the storage nodes 50. The present invention forms the storage nodes 50 and then electrically isolates the storage nodes 50 by using insulation material of the gate oxide layer 52; therefore, the storage nodes 50 are prevented from merging, even as the size of the flash memory device 10 is reduced.

FIG. 8 to FIG. 10 illustrate a method for preparing a multi-level flash memory device 60 according to another embodiment of the present invention. The fabrication processes shown in FIGS. 1-5 are repeated, and the deposition process and the spacer etching process are then performed to form a spacer 98 such as a polysilicon spacer in the depression 46, i.e., on the sidewall of the spacer 38. The charge-trapping layer 24 is used as the etch stop layer for the spacer etching process, and a portion of the top dielectric layer 26 not covered by the spacer 98 is removed from the charge-trapping layer 24 by the spacer etching process, as shown in FIG. 8. In one embodiment of the present invention, the spacer 98 is formed of polysilicon, while the spacer 38 and the dielectric layer 42 are formed of silicon oxide. Therefore, the spacer etching process can selectively remove the polysilicon to form the spacer 98.

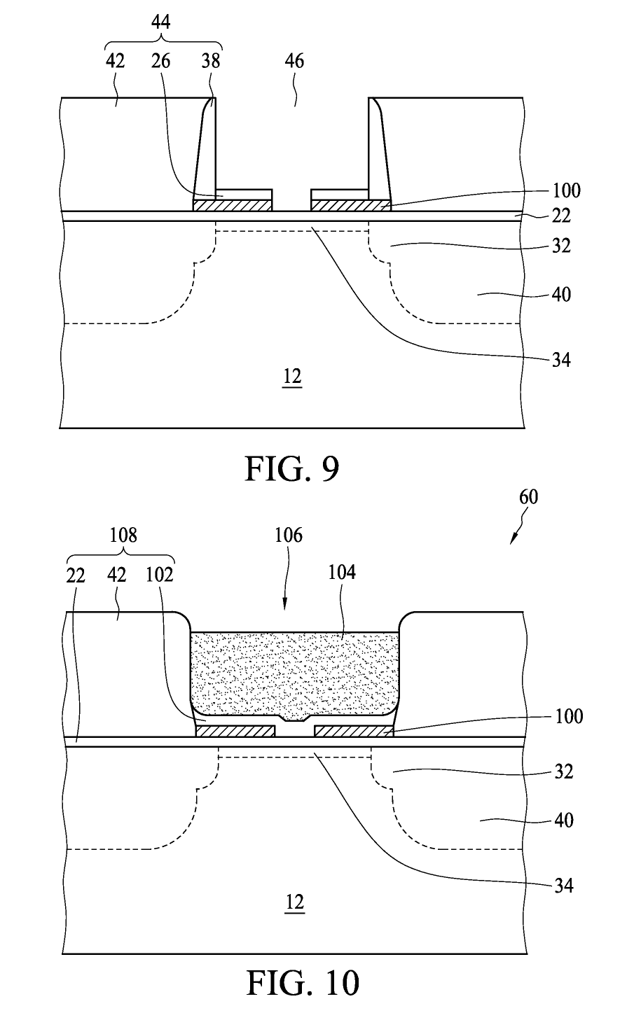

Referring to FIG. 9, the polysilicon spacer 98 is stripped from the top dielectric layer 26, and an etching process such as a wet etching process is then performed to remove a portion of the charge-trapping layer 24 not covered by the top dielectric layer 26 such that the charge-trapping layer 24 is segmented to form a plurality of storage nodes 100 on the bottom dielectric layer 22. In one embodiment of the present invention, the top dielectric layer 26 is formed of silicon oxide, and the etching process can selectively remove the charge-trapping layer 24 including silicon nitride from the depression 46.

Referring to FIG. 10, a wet etching process is performed to enlarge the depression 46 by removing the spacer 38 and the top dielectric layer 26 such that the storage nodes 100 are positioned below the enlarged depression 46, an oxidation process such as the wet oxidation process is then performed to form a gate oxide layer 102 between the storage nodes 100 and covers the storage nodes 100 to electrically isolate the storage nodes 100, and a damascene gate 106 including a polysilicon layer 104 filling the enlarged depression 46 is formed by the deposition process followed by the etching process.

The bottom dielectric layer 22, the dielectric layer 42 and the gate oxide layer 102 can be considered as a dielectric structure 108 positioned on the semiconductor substrate 12, while the storage nodes 100 are embedded in the dielectric structure 108. In particular, the storage nodes 100 are positioned right below the polysilicon layer 104 of the damascene gate 106. Furthermore, the gate oxide layer 102 of the dielectric structure 108 is positioned between the storage nodes 100 and covers the storage nodes 100, and the polysilicon layer 104 of the damascene gate 106 is positioned on the gate oxide layer 102. The polysilicon layer 104 of the damascene gate 106 is positioned in the dielectric structure 108 and above the storage nodes 100. The present invention forms the storage nodes 100 and then electrically isolates the storage nodes 100 by using insulation material of the gate oxide layer 102; therefore, the storage nodes 100 are prevented from merging, even as the size of the flash memory device 60 is reduced.

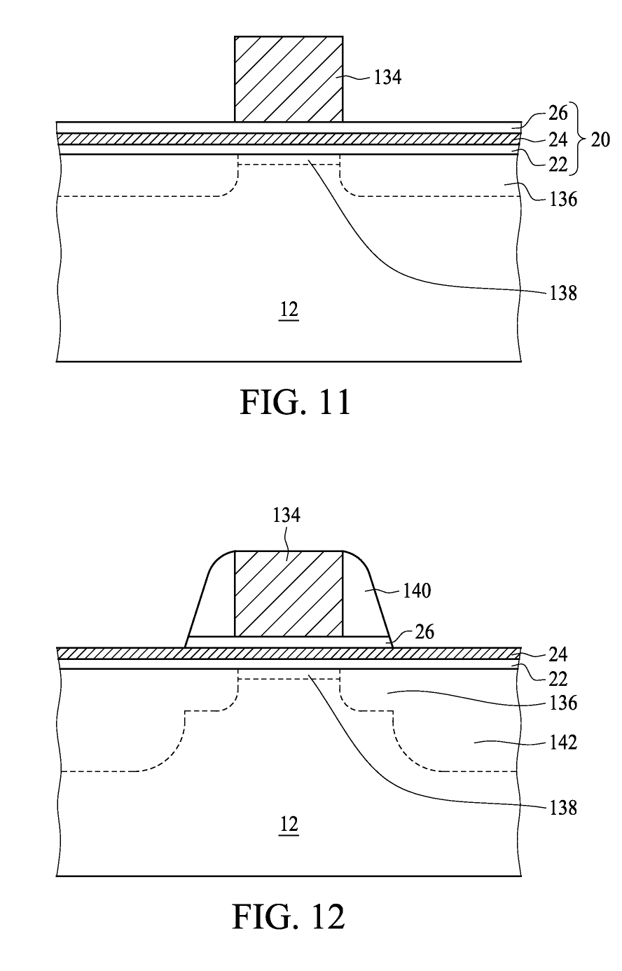

FIG. 11 to FIG. 17 illustrate a method for preparing a multi-level flash memory device 110 according to another embodiment of the present invention. The fabrication processes shown in FIGS. 1-2 are repeated, and a wet etching process is then performed to shrink the dielectric block 36 to form a dielectric block 134, and an implanting process is performed to form lightly doped regions 136 in the semiconductor substrate 12 adjacent to the dielectric block 134. In particular, a carrier channel 138 is formed between the lightly doped regions 136 in the semiconductor substrate 12, as shown in FIG. 11.

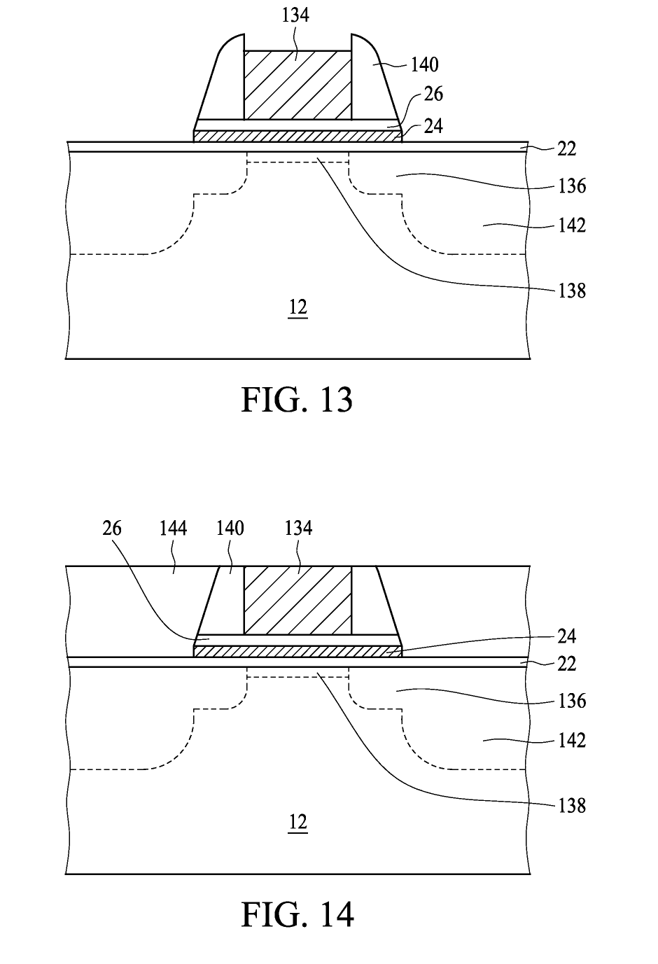

Referring to FIG. 12, a spacer 140 is formed on the sidewall of the dielectric block 134 by using the deposition process followed by the spacer etching process, and an implanting process is then performed to form heavily doped regions 142 in the semiconductor substrate 12 adjacent to the spacer 140. In one embodiment of the present invention, the spacer 140 is formed of silicon oxide, and the etching process removes a portion of the top dielectric layer 26 to expose the charge-trapping layer 24. Subsequently, an etching process is performed to remove a portion of the dielectric block 134 and the charge-trapping layer 24 not covered by the spacer 140 and the top dielectric layer 26, as shown in FIG. 13.

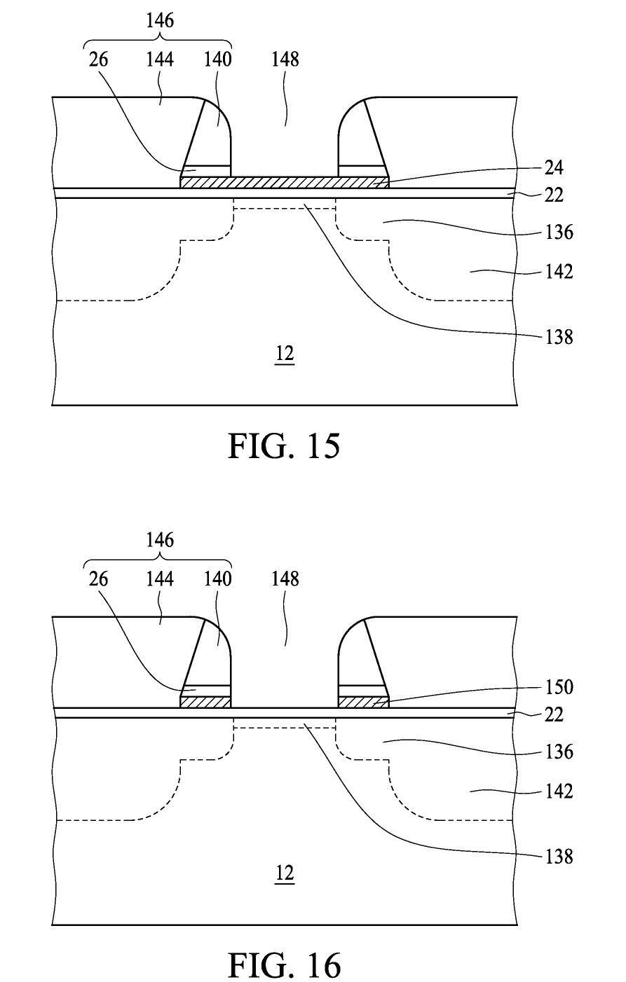

Referring to FIG. 14, a deposition process is performed to form a dielectric layer 144 on the semiconductor substrate 12 followed by a planarization process such as the chemical-mechanical polishing process. Subsequently, an etching process is performed to remove the dielectric block 134 to form a depression 148 in the spacer 140, and another etching process is then performed to remove a portion of the top dielectric layer 26 below the dielectric block 134 so as to expose the charge-trapping layer 24, as shown in FIG. 15. In one embodiment of the present invention, the dielectric layer 144 is formed of silicon oxide, and the etching process can selectively remove the dielectric block 134 including silicon nitride. In particular, the top dielectric layer 26, the spacer 140 and the dielectric layer 144 form an insulation structure 146 with the depression 148 positioned inside the insulation structure 146.

Referring to FIG. 16, an etching process such as a wet etching process is performed to remove a portion of the charge-trapping layer 24 not covered by the top dielectric layer 26 such that the charge-trapping layer 24 is segmented to form a plurality of storage nodes 150 on the bottom dielectric layer 22. In one embodiment of the present invention, the top dielectric layer 26 is formed of silicon oxide, and the etching process can selectively remove the charge-trapping layer 24 including silicon nitride from the depression 148.

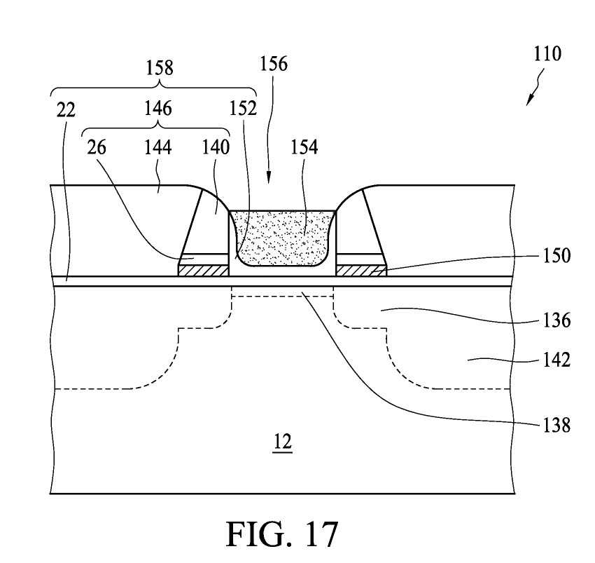

Referring to FIG. 17, an oxidation process such as the wet oxidation process is performed to form a gate oxide layer 152 between the storage nodes 150 and on the sidewall of the spacer 140 to electrically isolate the storage nodes 150, and a damascene gate 156 including a polysilicon layer 154 filling the depression 148 is formed by the deposition process followed by the etching process. In particular, the polysilicon layer 154 is positioned between the storage nodes 150.

The bottom dielectric layer 22, the insulation structure 146 and the gate oxide layer 152 can be considered as a dielectric structure 158 positioned on the semiconductor substrate 12, while the storage nodes 150 are embedded in the dielectric structure 158. In addition, the carrier channel 138 is positioned between the lightly doped regions 136 in the semiconductor substrate 12, and the storage nodes 150 are not positioned on the carrier channel 138 but completely on the lightly doped regions 136. Furthermore, the gate oxide layer 152 of the dielectric structure 158 is positioned between the storage nodes 150 and has a concave shape, and the polysilicon layer 154 of the damascene gate 156 is positioned in the concave of the gate oxide layer 152. The polysilicon layer 154 of the damascene gate 156 is positioned in the dielectric structure 158 and above the storage nodes 150. In addition, the polysilicon layer 154 is positioned completely between the storage nodes 150. The present invention forms the storage nodes 150 and then electrically isolates the storage nodes 150 by using insulation material of the gate oxide layer 152; therefore, the storage nodes 152 are prevented from merging, even as the size of the flash memory device 110 is reduced.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for preparing a multi-level flash memory device, comprising:
forming a dielectric stack including a charge-trapping layer on a semiconductor substrate;
forming an insulation structure having a depression on the charge-trapping layer;
removing a portion of the charge-trapping layer from the depression such that the charge-trapping layer is segmented to form a plurality of storage nodes;
forming a gate oxide layer isolating the storage nodes; and
forming a damascene gate including a polysilicon layer filling the depression.

2. The method for preparing a multi-level flash memory device of claim 1, wherein the forming of the insulation structure having the depression on the charge-trapping layer includes:
forming a dielectric block on the dielectric stack;
forming a first spacer on the sidewall of the dielectric block;
removing a portion of the charge-trapping layer not covered by the dielectric block and the first spacer;
forming a dielectric layer on the semiconductor substrate; and
removing the dielectric block to form the depression in the first spacer.

3. The method for preparing a multi-level flash memory device of claim 2, wherein the forming of the storage nodes includes:
forming a second spacer in the depression, wherein the second spacer is formed on the sidewall of the first spacer; and
removing a portion of the charge-trapping layer not covered by the second spacer to form the storage nodes.

4. The method for preparing a multi-level flash memory device of claim 3, wherein the first spacer and the second spacer include silicon oxide.

5. The method for preparing a multi-level flash memory device of claim 3, wherein the polysilicon layer is formed in the second spacer and on the gate oxide layer.

6. The method for preparing a multi-level flash memory device of claim 2, wherein the dielectric stack includes a top dielectric layer, and the forming of the storage nodes includes:
forming a second spacer in the depression, wherein the second spacer is formed on the sidewall of the first spacer;
removing a portion of the top dielectric layer not covered by the second spacer; and
removing a portion of the charge-trapping layer not covered by the top dielectric layer to form the storage nodes.

7. The method for preparing a multi-level flash memory device of claim 6, wherein the first spacer includes silicon oxide and the second spacer includes polysilicon.

8. The method for preparing a multi-level flash memory device of claim 6, further comprising removing the second spacer from the depression.

9. The method for preparing a multi-level flash memory device of claim 6, further comprising enlarging the depression such that the storage nodes are formed below the depression.

10. The method for preparing a multi-level flash memory device of claim 1, wherein the forming of the insulation structure having the depression on the charge-trapping layer includes:
forming a dielectric block on the dielectric stack;
performing a wet etching process to shrink the dielectric block;
forming a first spacer on the sidewall of the dielectric block;
removing a portion of the charge-trapping layer not covered by the dielectric block and the first spacer;
forming a dielectric layer on the semiconductor substrate; and
removing the dielectric block to form the depression in the first spacer.

11. The method for preparing a multi-level flash memory device of claim 10, wherein the forming of the storage nodes includes removing a portion of the charge-trapping layer under the dielectric block.

12. The method for preparing a multi-level flash memory device of claim 1, wherein the gate oxide layer is formed between the storage nodes.

13. The method for preparing a multi-level flash memory device of claim 1, wherein the gate oxide layer is formed between the storage nodes and covers the storage nodes.

14. The method for preparing a multi-level flash memory device of claim 1, wherein the gate oxide layer is formed between the storage nodes and on the sidewall of the first spacer.

15. The method for preparing a multi-level flash memory device of claim 1, further comprising:
forming a lightly doped region in the semiconductor substrate before forming the first spacer; and
forming a heavily doped region in the semiconductor substrate after forming the first spacer.
